(19) United States
(12) Patent Application Publication
(10) Pub. No.: US 2014/0116754 A1
(43) Pub. Date: May 1, 2014

(54) CONDUCTIVE STRUCTURE OF TRANSPARENT CONDUCTIVE FILM, TRANSPARENT CONDUCTIVE FILM AND PREPARATION METHOD THEREOF

(71) Applicant: NANCHANG O-FILM TECH. CO. LTD., Jiangxl (CN)

(72) Inventors: Yulong Gao, JIANGXI (CN); Zheng Cui, JIANGSU (CN); Chao Sun, JIANGXI (CN)

(73) Assignee: NANCHANG O-FILM TECH. CO., LTD, JIANGXI 330013 (CN)

(21) Appl. No.: 13/985,768

(22) PCT Filed: Dec. 20, 2012
(86) PCT No.: PCT/CN2012/087079

§ 371 Date: Aug. 15, 2013

(30) Foreign Application Priority Data
Oct. 25, 2012 (CN) 201210412895.0

(51) Int. Cl. H05K 1/02

(52) U.S. Cl. CPC H05K 1/0213
USPC 174/250

(57) ABSTRACT

The present invention discloses a conductive structure of a transparent conductive film, the transparent conductive film and a preparation method thereof, wherein the transparent conductive film has a single-sided double-layer conductive structure, which includes a first metal embedded layer embossed on the substrate or on the polymer layer on the surface of the substrate, and a second metal embedded layer embossed on the polymer material applied onto the surface of the first metal embedded layer. The first and second layers of the conductive structure have a grid recess structure, with all the recesses filled with the conductive material. The single-sided double-layer graphic transparent conductive film provided by the present invention has a high resolution, a high transmittance, an independently adjustable sheet resistance, and many other advantages. The transparent conductive film can reduce the cost as well as weight and thickness of the touch panel.

### FIELD OF THE INVENTION

The present invention relates to the field of multi-touch display, and particularly relates to a transparent conductive film supporting the multi-touch technology and the preparation method thereof.

### BACKGROUND OF THE INVENTION

The transparent conductive film is a film having good electrical conductivity, and a high visible light transmittance. The transparent conductive film has been widely used in flat panel displays, photovoltaic devices, touch panels and electromagnetic shielding, and other fields, having a very broad market space.

An ITO layer is a vital component in the touchscreen module. Although the touchscreen manufacturing technology develops rapidly, the ITO layer based manufacturing process, taking the projected capacitive screen for example, has not changed much in recent years. ITO coating, graphic ITO, and transparent electrode silver wire production are always inevitably needed. The traditional production process is complex and lengthy, and therefore yield control has become an unavoidable problem in the field of touchscreen manufacturing at the present stage. In addition, an etching process also inevitably needs to be used in the approach, which will waste a great deal of ITO and metal materials. Therefore, how to achieve a simple and environmental protective process of manufacturing the transparent conductive film is a key technical problem that urgently needs to be solved.

A Chinese Application CN201010533228 disclosed an embedded graphic metal grid transparent conductive film, in which a grid-shaped recess is formed by embossing on the thermoplastic substrate material and filled with a conductive metal, the blank region of the grid being used for transmitting light, the metal in the recessed region of the grid being used for achieving the conductive function. The transmittance of the transparent conductive film on the PET substrate is greater than 87%, while the transmittance of the transparent conductive film on the glass substrate is greater than 90%; both of them have a sheet resistance less than 10 Ω/sq; especially the resolution of the metal lines is less than 3 μm.

Another Chinese patent CN201110058431 disclosed another embedded graphic metal grid transparent conductive film, in which a polymer layer was prepared on the surface of the substrate, and a grid graph was embossed on the polymer layer, thereby preparing the metal embedded layer.

The above two patents both disclosed preparation of the transparent conductive film having a single-layer conductive structure. However, the single-layer transparent conductive film is difficult to support the multi-touch technology. Therefore, in order to realize the multi-touch technology, two pieces of the single-layer transparent conductive film are used in the prior art so as to jump wire to achieve conduction to each other in the X- and Y-axis directions, thus overcoming the defect that the single-layer film does not support the multi-touch technology. However, the solution of using two pieces of the transparent conductive film has the following defects: Firstly, jump wire is realized mainly by using yellow light, which has a complicated process; besides, the jump wire is visible on the touchscreen, which will affect the appearance. Secondly, the development direction of the existing touchscreen is to be lighter and thinner; if one layer of the conductive film is added, i.e. a double-layer conductive film is used for touching, thickness and weight will certainly be bound to increase at the expense, which does not meet the development trend.

For this the inventor proposed a single-sided double-layer graphic transparent conductive film, so to solve the technical defects existing in the prior art.

### SUMMARY OF THE INVENTION

In view of this, a first purpose of the present invention is to provide a single-sided double-layer graphic conductive structure, making the transparent conductive film having the conductive structure support the multi-touch function. A second purpose of the present invention is to provide a transparent conductive film having the above conductive structure and the preparation method thereof, which can not only support the multi-touch function but also consumedly reduce the thickness of the entire multi-touch display device.

According to the conductive structure of a transparent conductive film provided by one of the purposes of the present invention, the conductive structure is formed on a transparent substrate including a grid-shaped first metal embedded layer and a grid-shaped second metal embedded layer located on the first metal embedded layer, the first metal embedded layer and the second metal embedded layer being insulated from each other.

A transparent conductive film provided according to the other purpose of the present invention includes a transparent substrate and the conductive structure arranged on the substrate, the conductive structure including a grid-shaped first metal embedded layer and a grid-shaped second metal embedded layer located on the first metal embedded layer, the first metal embedded layer and the second metal embedded layer being insulated from each other.

A transparent conductive film supporting the multi-touch function provided according to the other purpose of the present invention includes a functional region and a wiring region arranged on at least one side of the periphery of the functional region; wherein the functional region includes a conductive structure, which includes a grid-shaped first metal embedded layer and a grid-shaped second metal embedded layer located on the first metal embedded layer, the first metal embedded layer and the second metal embedded layer being insulated from each other; the wiring region includes a first wiring region formed by convergence of a plurality of wires that are connected to the first metal embedded layer and a second wiring region formed by convergence of a plurality of wires that are connected to the second metal embedded layer, the first wiring region and the second wiring region being insulated from each other.

Preferably, the transparent conductive film includes a transparent substrate and a transparent polymer layer arranged on the substrate, the first metal embedded layer and the first wiring region being arranged on the substrate, the second metal embedded layer and the second wiring region being arranged in the polymer layer, thickness of the second metal embedded layer and of the wire connected thereto being less than that of the polymer layer.

The polymer layer is graphically applied onto the substrate, with the first wiring region exposed.

An adhesion-promoting layer is further arranged between the substrate and the polymer layer.

Preferably, the transparent conductive film includes a transparent substrate, a transparent first polymer layer located on the substrate, and a transparent second polymer layer located on the first polymer layer, the first metal embedded layer and the first wiring region being arranged in the first polymer layer, the second metal embedded layer and the second wiring region being arranged in the second polymer layer, thickness of the second metal embedded layer and of the wire connected thereto being less than that of the second polymer layer.

The second polymer layer is graphically applied onto the first polymer layer, with the first wiring region exposed.

Preferably, the grid of the first metal embedded layer and/or the second metal embedded layer is a random grid having an irregular shape.

The random grid is composed of irregular polygons; the grid line of the grid is a straight line segment, and forms an evenly-distributed angle θ with the rightward horizontal X axis.

Meanwhile, the present invention provides a preferred method of preparing the transparent conductive film, which includes the following steps:

(1) Graphically embossing the substrate material based on the embossing technology, so as to form a grid-shaped recess in the functional region and a wiring recess in the wiring region;

(2) filling the conductive material into the recess embossed in Step (1), so as to form the first metal embedded layer and the first wiring region;

(3) graphically coating the substrate based on Step (2), so as to form the polymer layer, which covers at least the first metal embedded layer in the functional region, with the first wiring region exposed;

(4) graphically embossing the polymer layer applied in Step (3) based on the embossing technology, so as to form a grid-shaped recess in the functional region and a wiring recess in the wiring region; and

(5) filling the conductive material into the recess embossed in Step (4), so as to form the second metal embedded layer and the second wiring region; the second wiring region does not overlap the first wiring region up and down.

Meanwhile, the present invention provides another preferred method of preparing the transparent conductive film, which includes the following steps:

(1) Coating the substrate with the first polymer layer;

(2) graphically embossing the first polymer layer based on the embossing technology, so as to form a grid-shaped recess in the functional region and a wiring recess in the wiring region;

(3) filling the conductive material into the recess embossed in Step (2), so as to form the first metal embedded layer and the first wiring region;

(4) graphically coating the substrate based on Step (3), so as to form the second polymer layer, which covers at least the first metal embedded layer in the functional region, with the first wiring region exposed;

(5) graphically embossing the second polymer layer applied in Step (4) based on the embossing technology, so as to form a grid-shaped recess in the functional region and a wiring recess in the wiring region; and

(6) filling the conductive material into the recess embossed in Step (5), so as to form the second metal embedded layer and the second wiring region; the second wiring region does not overlap the first wiring region up and down.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a schematic view of part of the transparent conductive film of the first embodiment of the present invention.

FIG. 2 is a schematic view of the transparent conductive film using the multi-touch function in the first embodiment of the present invention.

FIGS. 3-6 are state views of the steps of the method for preparing the transparent conductive film in the first embodiment of the present invention.

FIG. 7 is a variant structure of the first embodiment of the present invention.

FIG. 8 is a schematic view of part of the transparent conductive film of the second embodiment of the present invention.

FIG. 9 is a schematic view of the transparent conductive film using the multi-touch function in the second embodiment of the present invention.

FIGS. 10-13 are state views of the steps of the method for preparing the transparent conductive film in the second embodiment of the present invention.

### DETAILED DESCRIPTION

Two pieces of the single-layer transparent conductive film need to be used in the existing multi-touch technology, greatly increasing thickness of the entire touch display device, contrary to the development direction of the display device of being lighter and thinner. Therefore, the present invention proposes a single-sided double-layer transparent conductive film, which has a conductive structure composed of a grid-shaped first metal embedded layer and a grid-shaped second metal embedded layer, which are insulated from each other, making a single piece of the transparent conductive film support the multi-touch function, thus greatly reducing thickness of the touch display device.

The technical solution of the present invention will be described below in detail with reference to the specific embodiments.

### Example 1

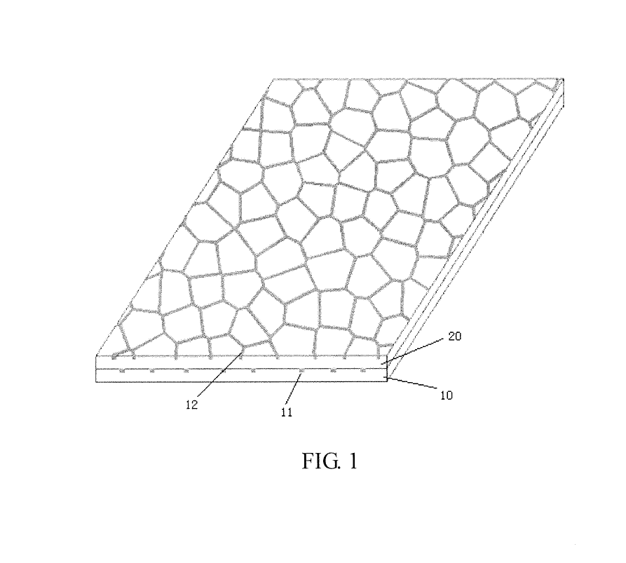

Referring to FIG. 1, which is a schematic diagram of part of the transparent conductive film of the first embodiment of the present invention. In this embodiment, the first metal embedded layer in the conductive structure is directly prepared on the substrate, as shown in the diagram, the transparent conductive film includes a transparent substrate 10 and a transparent polymer layer 20 arranged on the substrate. The conductive structure includes a grid-shaped first metal embedded layer 11 arranged in the substrate 1, and a grid-shaped second metal embedded layer 21 arranged in the transparent polymer layer 20; in order to ensure the first metal embedded layer 11 and the second metal embedded layer 21 to be insulated from each other, the thickness of the second metal embedded layer 21 is made to be less than that of the polymer layer 20, thereby part of the polymer layer 20 being arranged between the first metal embedded layer 11 and the second metal embedded layer 21 and thus achieving an insulating effect. The transparent substrate is made of a thermoplastic material, such as PMMA (polymethyl methacrylate) and PC (polycarbonate plastic), and the polymer layer 20 may be made of UV embossed plastic materials, etc. In order to guarantee light transmission of the transparent conductive film, these two layers are preferably to be made of a material with a high light transmittance.

Preferably, the grids of the first metal embedded layer 11 and/or the second metal embedded layer 21 are set to be random grids having an irregular shape, which are distributed evenly in each angular direction. Furthermore, these random grids are composed of irregular polygons; that is, the grid line of the grid is a straight line segment, and forms an evenly-distributed angle θ with the rightward horizontal X axis, the uniform distribution referring to the statistical value θ of each of the random grids; then gathering statistics for the probability pi of the grid lines falling within each of angle intervals at a stepper angle of 5°, thus obtaining p1, p2 . . . p36 in the 36 angle intervals within 0˜180°; pi satisfies that the standard deviation is less than 20% of the arithmetic mean. Such a uniform distribution in the angular direction can avoid generation of Moire stripe.

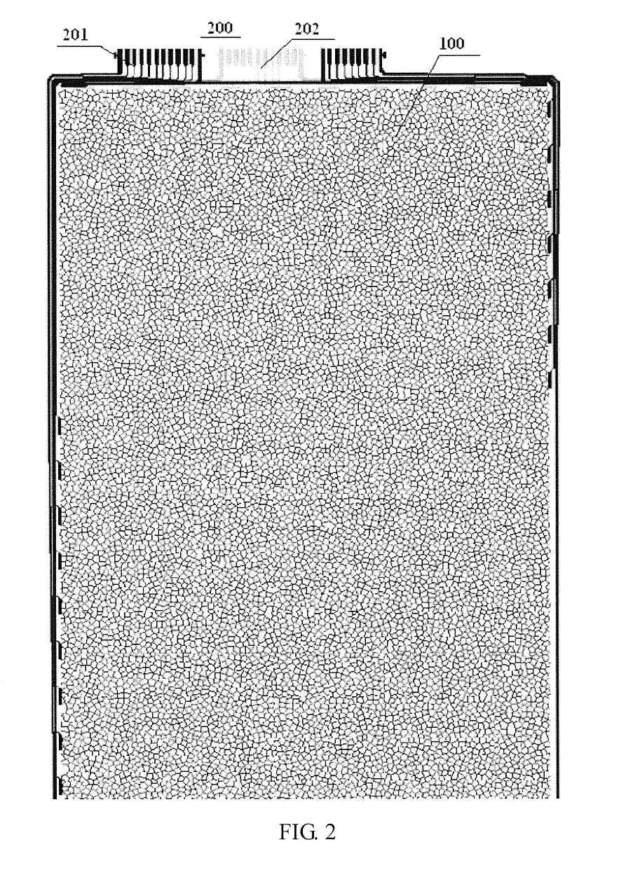

Referring to FIGS. 1 and 2, wherein FIG. 2 is a schematic diagram of the transparent conductive film using the multi-touch function in the first embodiment of the present invention. The transparent conductive film, based on the transparent conductive film in FIG. 1, has an additional wire at the periphery to meet the multi-touch function. As shown in the diagrams, the transparent conductive film includes a functional region 100 and a wiring region 200, wherein the functional region 100 refers to a region of the transparent conductive film used to be touched by a user for realizing the control function, and includes the conductive structure in the above first embodiment, i.e. a grid-shaped first metal embedded layer 11 and a grid-shaped second metal embedded layer 21 located on the first metal embedded layer. The wiring region 200, distributed on at least one side of the periphery of the functional region 100, includes a first wiring region 201 formed by convergence of a plurality of wires that are connected to the first metal embedded layer 11 and a second wiring region 202 formed by convergence of a plurality of wires that are connected to the second metal embedded layer 21, the first wiring region 201 and the second wiring region 202 being insulated from each other. In FIG. 2, because of the overlooking effect, the first metal embedded layer 11 is blocked, but it should be understood that the wires in the first wiring region 201 are connected to the first metal embedded layer. These wires are used for connecting the conductive structure in the functional region with an external data processing device (not shown), such that when an external touch action is detected in the functional region, the detection signal data can be transmitted to these data processing devices for instruction processing, so as to achieve the touch function.

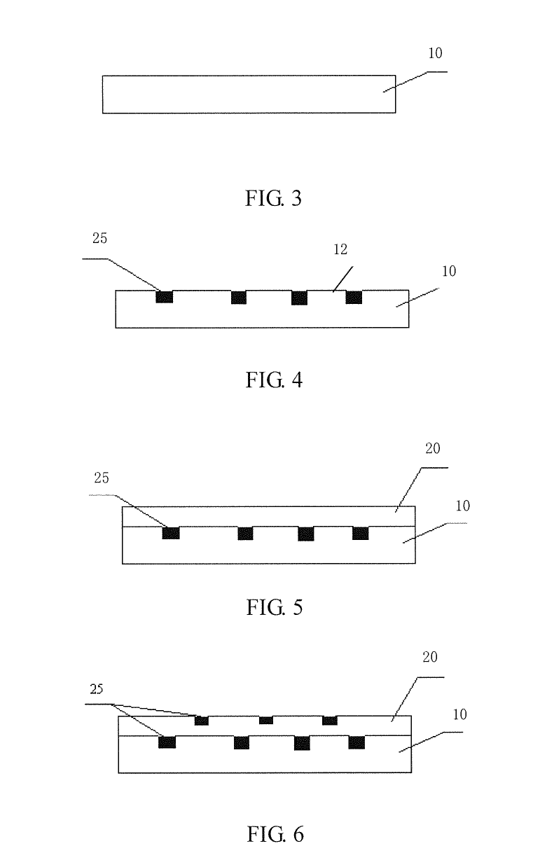

Referring to FIGS. 3-6, the method for preparing the transparent conductive film in the first embodiment includes the following steps:

1. First graphically embossing the substrate 10 by using the embossing technology, so as to form the grid-shaped recesses 12 in the functional region, these recesses 12 having a depth of 3 μm for example, and a width of 2.2 μm for example, with the grids being random grids having an irregular shape.

2. Then filling with the conductive material 25 by the scrape coating technology all of the graphic recesses formed by embossing the substrate 10 and sintering them, wherein the conductive material is for example nano silver ink having a solid content of silver ink of 35% and a sintering temperature of 150° C.; as shown in FIG. 4, in the substrate material 10 are formed the first metal embedded layer and the first wiring region having the conductive function.

3. Then graphically coating the substrate based on Step 2, so as to form the polymer layer 20, which covers at least the first metal embedded layer in the functional region, with the first wiring region exposed. The applied polymer layer is the UV embossed plastic for example, and has a thickness of 4 μm. Since the first wiring region needs to be externally connected to other data processing devices, these wires located in the first wiring region need to be exposed. Therefore, the present invention proposes the graphical coating process, which refers to partially coating the substrate 10 with the UV embossed plastic, so as to make all of the first metal embedded layer in the functional region covered, with the first wiring region in the wiring region exposed.

4. Graphically embossing the polymer layer applied in Step 3 based on the embossing technology, so as to form a grid-shaped recess in the functional region and a wiring recess in the wiring region. The purpose of this step is to form the second metal embedded layer and the second wiring region on the polymer layer 20, with the entire graphic embossing process similar to the embossing in Step 1. However, it needs to be indicated that in this step, when embossing to form the recess in the second metal embedded layer and the second wiring region, a process is necessary for aligning the first metal embedded layer and the first wiring region, which helps to avoid overlapping the first wiring region up and down when forming the wires in the second wiring region.

5. Filling the conductive material into the recess embossed in Step 4, so as to form the second metal embedded layer and the second wiring region; the second wiring region does not overlap the first wiring region up and down. This step, similar to Step 2, fills with the nano silver ink 25 by the inkjet filling technology the graphic grid recesses formed by embossing the UV embossed plastic surface and sinters them, with the silver ink 25 having a solid content of 35% and a sintering temperature of 150° C.; as shown in FIG. 6, in the UV embossed plastic are formed the second metal embedded layer and the second wiring region having the conductive function; the depth of the recess in the second metal embedded layer and the second wiring region is less than that of the UV embossed plastic.

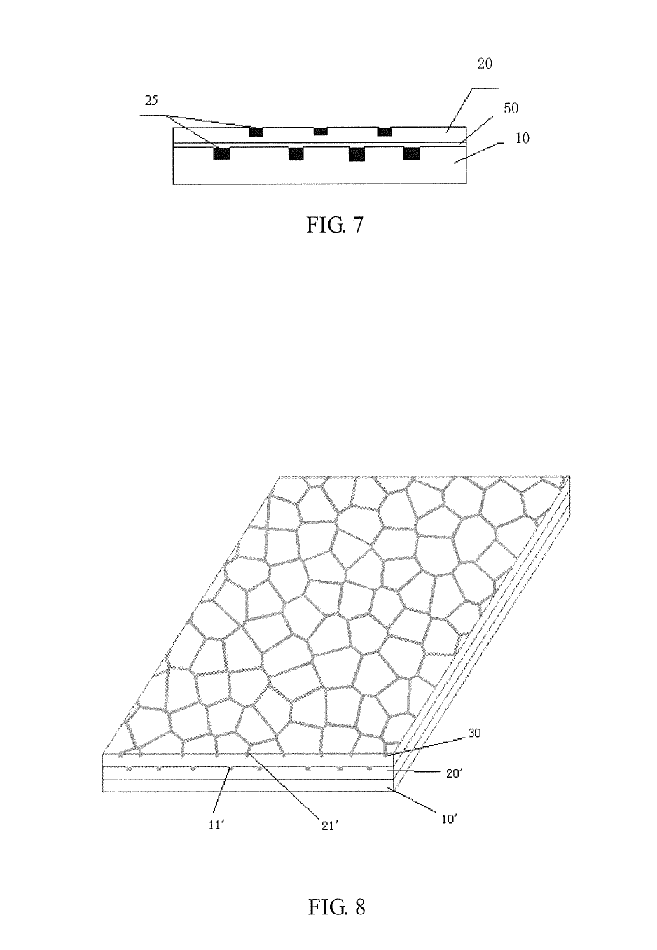

As shown in FIG. 7, an adhesion-promoting layer 50 can further be applied between the substrate 10 and the polymer layer 20, so as to increase the demand for adhesion of products.

### Example 2

Referring to FIG. 8, which is a schematic diagram of part of the transparent conductive film of the second embodiment of the present invention. In the embodiment, the first metal embedded layer in the conductive structure is directly prepared in the first polymer layer on the substrate. As shown in the diagram, the transparent conductive film includes a transparent substrate 10′, a transparent first polymer layer 20′ located on the substrate, and a transparent second polymer layer 30 located on the first polymer layer 20′. The conductive structure includes a grid-shaped first metal embedded layer 11′ arranged in the first polymer layer 20′, and a grid-shaped second metal embedded layer 21′ arranged in the second transparent polymer layer 30. In order to ensure the first metal embedded layer 11′ and the second metal embedded layer 21′ to be insulated from each other, the thickness of the second metal embedded layer 21′ is made to be less than that of the second polymer layer 30, thereby part of the second polymer layer 30 being arranged between the first metal embedded layer 11′ and the second metal embedded layer 21′ and thus achieving an insulating effect. The transparent substrate is made of a flexible material and a rigid thermoplastic material for example, such as PET (polyethylene terephthalate plastic) and PC (polycarbonate plastic), and the first polymer layer 20′ and the second polymer layer 30 are for example made of a UV embossed plastic material, etc. In order to guarantee light transmission of the transparent conductive film, these three layers are preferably to be made of a material with a high light transmittance.

Preferably, the grids of the first metal embedded layer 11′ and/or the second metal embedded layer 21′ are set to be random grids having an irregular shape, which are distributed evenly in each angular direction. Furthermore, these random grids are composed of irregular polygons, that is, the grid line of the grid is a straight line segment, and forms an evenly-distributed angle θ with the rightward horizontal X axis, the uniform distribution referring to the statistic value θ of each of the random grids; then gathering statistics for the probability pi of the grid lines falling within each of angle intervals at a stepper angle of 5°, thus obtaining p1, p2 . . . p36 in the 36 angle intervals within 0˜180°; pi satisfies that the standard deviation is less than 20% of the arithmetic mean. Such a uniform distribution in the angular direction can avoid generation of Moire stripe.

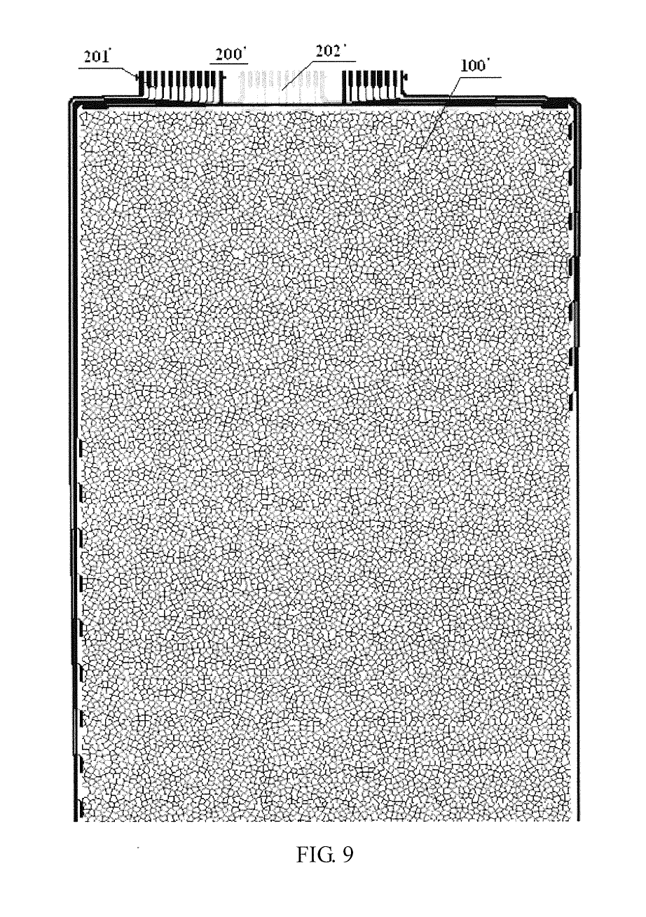

Referring to FIGS. 8 and 9, in which FIG. 9 is a schematic diagram of the transparent conductive film using the multi-touch function in the second embodiment of the present invention. The transparent conductive film, based on the transparent conductive film in FIG. 8, has an additional wire at the periphery to meet the multi-touch function. As shown in the diagram, the transparent conductive film includes a functional region 100′ and a wiring region 200′, wherein the functional region 100′ refers to a region of the transparent conductive film used to be touched by a user for realizing the control function, and includes the conductive structure in the above first embodiment, i.e. a grid-shaped first metal embedded layer 11′ and a grid-shaped second metal embedded layer 21′ located on the first metal embedded layer. The wiring region 200′, distributed on at least one side of the periphery of the functional region 100′, includes a first wiring region 201′ formed by convergence of a plurality of wires that are connected to the first metal embedded layer 11′ and a second wiring region 202′ formed by convergence of a plurality of wires that are connected to the second metal embedded layer 21′, the first wiring region 201′ and the second wiring region 202′ being insulated from each other. In FIG. 9, because of the overlooking effect, the first metal embedded layer 11′ is blocked, but it should be understood that the wires in the first wiring region 201′ are connected to the first metal embedded layer. These wires are used for connecting the conductive structure in the functional region with an external data processing device (not shown in the diagram), such that when an external touch action is detected in the functional region, the detection signal data can be transmitted to these data processing devices for instruction processing, so as to achieve the touch function.

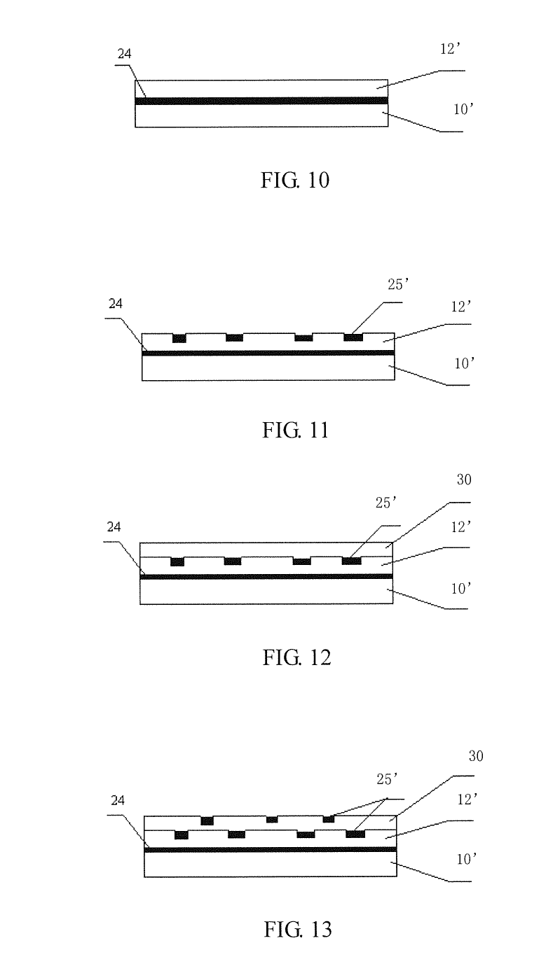

Referring to FIGS. 10-13, the method for preparing the transparent conductive film in the second embodiment includes the following steps:

1. First coating the substrate 10′ with the UV embossed plastic to form the first polymer layer 20′. The substrate 10′ is made of PET for example, and has a width of 125 μm for example, with the UV embossed plastic having a thickness of 4 um for example.

2. Then graphically embossing the first polymer layer based on the embossing technology, so as to form the grid-shaped recesses 12′ in the functional region. The recess 12′ has a depth of 3μm and a width of 2.2 μm, with the grids being random grids having an irregular shape.

3. Then filling the conductive material into the recess embossed in Step 2, so as to form the first metal embedded layer and the first wiring region. In this step, the graphic grid recesses formed by embossing the UV embossed plastic surface and sintering them are filled with the nano silver ink 25′ by the scrape coating technology, with the silver ink 25′ having a solid content of 35% and a sintering temperature of 150° C. As shown in FIG. 11, the first metal embedded layer and the first wiring region having the conductive function are formed in the first polymer layer 20′.

4. Then graphically coating the substrate based on Step 3, so as to form the second polymer layer, which covers at least the first metal embedded layer in the functional region, with the first wiring region exposed. As shown in FIG. 12, the UV embossed plastic is graphically applied onto the surface of the finished UV embossed plastic, so as to form the second polymer layer 30, which has a thickness of 4 μm for example. To be the same as in Example 1, since the first wiring region needs to be externally connected to other data processing devices, the wires located in the first wiring region need to be exposed. Therefore, the present invention proposes the graphical coating process, which refers to partially coating the first polymer layer 20′ with the UV embossed plastic, so as to make all of the first metal embedded layer in the functional region covered, with the first wiring region in the wiring region exposed.

5. Then graphically embossing the second polymer layer applied in Step 4 based on the embossing technology, so as to form a grid-shaped recess in the functional region and a wiring recess in the wiring region. The purpose of this step is to form the second metal embedded layer and the second wiring region on the second polymer layer 30, with the entire graphic embossing process similar to the embossing in Step 2. However, it needs to be indicated that in this step, when embossing to form the recess in the second metal embedded layer and the second wiring region, a process is necessary for aligning the first metal embedded layer and the first wiring region, which helps to avoid overlapping the first wiring region up and down when forming the wires in the second wiring region.

6. Then filling the conductive material into the recess embossed in Step 5, so as to form the second metal embedded layer and the second wiring region; the second wiring region does not overlap the first wiring region up and down. In this step, similar to Step 3, the graphic grid recesses formed by embossing the UV embossed plastic surface and sintering them are filled with the nano silver ink 25 by the inkjet filling technology, with the silver ink 25′ having a solid content of 35% and a sintering temperature of 150° C. As shown in FIG. 13, the second metal embedded layer and the second wiring region having the conductive function are formed in the UV embossed plastic. The depth of the recess in the second metal embedded layer and the second wiring region is less than that of the UV embossed plastic.

Preferably, an adhesion-promoting layer is further arranged between the substrate 10′ and the first polymer layer 20′ and/or between the first polymer layer 20′ and the second polymer layer 30. The adhesion-promoting layer 24 as shown in the diagram serves to strengthen the adhesion between the layers.

It needs to be explained that the size parameters exemplified in each of the above examples are merely used for illustrating the implementation states of the present invention. Taking the width of the recess as an example, the width of the recess is acceptable so long as it is less than the resolution limit of the human eye, i.e. it does not affect the normal viewing as a display device. While for the depth of the recess, it should, based on being less than the polymer layer, make the cross-sectional area of the metal embedded layer as large as possible, so as to reduce the resistance of the metal lines.

The substrate material and the thermoplastic substrate material in a single-sided double-layer graphic transparent conductive film and the preparation method thereof in the above examples are not limited to the materials enumerated in the examples, and may also be glass, quartz, polymethyl methacrylate (PMMA), polycarbonate (PC) and the like. The embossing technology mentioned in the examples includes hot embossing and UV embossing. The applied UV embossed plastic mentioned in the examples is not limited to these, and can also be other polymers having the similar properties; the method for filling the conductive material mentioned in the examples includes scrape coating and inkjet printing. The conductive material mentioned in the present invention is not limited to silver, and can also be graphite, a macromolecular conductive material, etc.

Although the invention has been described in language specific to structural features and/or methodological acts, it is to be understood that the invention defined in the appended claims is not necessarily limited to the specific features or acts described. Rather, the specific features and acts are disclosed as sample forms of implementing the claimed invention.

What is claimed is:

1. A conductive structure of a transparent conductive film formed on a transparent substrate, wherein the conductive structure comprises a grid-shaped first metal embedded layer and a grid-shaped second metal embedded layer located on the first metal embedded layer, the first metal embedded layer and the second metal embedded layer are insulated from each other.

2. A transparent conductive film, comprising a transparent substrate and a conductive structure arranged on the substrate, wherein the conductive structure comprises a grid-shaped first metal embedded layer and a grid-shaped second metal embedded layer located on the first metal embedded layer, the first metal embedded layer and the second metal embedded layer are insulated from each other.

3. A transparent conductive film for supporting a multi-touch function, comprising a functional region and a wiring region arranged on at least one side of periphery of the functional region, wherein the functional region includes a conductive structure, which includes a grid-shaped first metal embedded layer and a grid-shaped second metal embedded layer located on the first metal embedded layer, the first metal embedded layer and the second metal embedded layer being insulated from each other;
the wiring region includes a first wiring region formed by convergence of a plurality of wires that are connected to the first metal embedded layer and a second wiring region formed by convergence of a plurality of wires that are connected to the second metal embedded layer, the first wiring region and the second wiring region are insulated from each other.

4. The transparent conductive film according to claim 3, further comprising a transparent substrate and a transparent polymer layer arranged on the substrate, the first metal embedded layer and the first wiring region being arranged on the substrate, the second metal embedded layer and the second wiring region being arranged in the polymer layer, a thickness of the second metal embedded layer and of the wire connected thereto is less than that of the polymer layer.

5. The transparent conductive film according to claim 4, wherein the polymer layer is graphically applied onto the substrate, and first wiring region is exposed.

6. The transparent conductive film according to claim 4, wherein an adhesion-promoting layer is further arranged between the substrate and the polymer layer.

7. The transparent conductive film according to claim 3, wherein the transparent conductive film comprises a transparent substrate, a transparent first polymer layer located on the substrate, and a transparent second polymer layer located on the first polymer layer, the first metal embedded layer and the first wiring region being arranged in the first polymer layer, the second metal embedded layer and the second wiring region being arranged in the second polymer layer, thickness of the second metal embedded layer and of the wire connected thereto being less than that of the second polymer layer.

8. The transparent conductive film according to claim 7, wherein the second polymer layer is graphically applied onto the first polymer layer, with the first wiring region exposed.

9. The transparent conductive film according to Claim 3, wherein the grid of the first metal embedded layer and/or the second metal embedded layer is a random grid having an irregular shape.

10. The transparent conductive film according to claim 9, wherein the random grid is composed of irregular polygons; the grid line of the grid is a straight line segment, and forms an evenly-distributed angle θ with a rightward horizontal X axis.

11. A method for preparing the transparent conductive film according to claim 4, comprising the following steps:
(1) graphically embossing the substrate material based on an embossing technology, so as to form a grid-shaped recess in the functional region and a wiring recess in the wiring region;
(2) filling the conductive material into the recess embossed in Step (1), so as to form a first metal embedded layer and a first wiring region;
(3) graphically coating the substrate based on Step (2), so as to form the polymer layer, which covers at least the first metal embedded layer in the functional region, with the first wiring region exposed;
(4) graphically embossing the polymer layer applied in Step (3) based on the embossing technology, so as to form a grid-shaped recess in the functional region and a wiring recess in the wiring region; and
(5) filling the conductive material into the recess embossed in Step (4), so as to form the second metal embedded layer and the second wiring region; the second wiring region does not overlap the first wiring region up and down.

12. A method for preparing the transparent conductive film according to claim 7, comprising the following steps:
(1) coating the substrate with the first polymer layer;
(2) graphically embossing the first polymer layer based on the embossing technology, so as to form a grid-shaped recess in the functional region and a wiring recess in the wiring region;
(3) filling the conductive material into the recess embossed in Step (2), so as to form the first metal embedded layer and the first wiring region;
(4) graphically coating the substrate based on Step (3), so as to form the second polymer layer, which covers at least the first metal embedded layer in the functional region, with the first wiring region exposed;
(5) graphically embossing the second polymer layer applied in Step (4) based on the embossing technology, so as to form a grid-shaped recess in the functional region and a wiring recess in the wiring region; and
(6) filling the conductive material into the recess embossed in Step (5), so as to form the second metal embedded layer and the second wiring region; the second wiring region does not overlap the first wiring region up and down.

13. The transparent conductive film according to claim 4, wherein the grid of the first metal embedded layer and/or the second metal embedded layer is a random grid having an irregular shape.

14. The transparent conductive film according to claim 13, wherein the random grid is composed of irregular polygons; the grid line of the grid is a straight line segment, and forms an evenly-distributed angle θ with a rightward horizontal X axis.

15. The transparent conductive film according to claim 7, wherein the grid of the first metal embedded layer and/or the second metal embedded layer is a random grid having an irregular shape.

16. The transparent conductive film according to claim 15, wherein the random grid is composed of irregular polygons; the grid line of the grid is a straight line segment, and forms an evenly-distributed angle θ with a rightward horizontal X axis.
